(19) United States
(12) Patent Application Publication
(10) Pub. No.: US 2009/0278120 A1
(43) Pub. Date: Nov. 12, 2009

(54) Thin Film Transistor

(75) Inventors: Sang Yeol LEE, Seoul (KR); Seongpil CHANG, Seoul (KR)

Correspondence Address: FENWICK & WEST LLP, SILICON VALLEY CENTER, 801 CALIFORNIA STREET, MOUNTAIN VIEW, CA, 94041, US

(73) Assignee: KOREA INSTITUTE OF SCIENCE AND TECHNOLOGY, Seoul (KR)

(21) Appl. No.: 12/265,139

(22) Filed: Nov. 5, 2008

(30) Foreign Application Priority Data
May 9, 2008 (KR) 10-2008-0043329
Sep. 9, 2008 (KR) 10-2008-0088905

(51) Int. Cl. H01L 29/786

(52) U.S. Cl. 257/43; 257/E29.296

(57) ABSTRACT

There is provided a thin film transistor (TFT) capable of improving electron mobility and minimizing the occurrence of hysteresis due to traps. The TFT includes a channel layer and a gate insulating layer, wherein the channel layer is made of an oxide semiconductor. In the TFT, the gate insulating layer includes one or more first dielectric layer and a second dielectric layer, and the first dielectric layer has a dielectric constant different from that of the second dielectric layer.

### PRIORITY STATEMENT

This application claims priority under 35 U.S.C. §119(a) to Republic of Korea Patent Application No. 10-2008-0043329, filed on May 9, 2008 and Republic of Korea Patent Application No. 10-2008-0088905, filed on Sep. 9, 2008, in the Korean Intellectual Property Office (KIPO), the entire contents of which are incorporated herein by reference.

### BACKGROUND

1. Technical Field

Example embodiments relate to a thin film transistor, and more particularly, to a thin film transistor capable of improving electron mobility and minimizing the occurrence of hysteresis due to traps.

2. Discussion of the Related Art

A flat panel display such as an organic light emitting diode (OLED) or a liquid crystal display (LCD) has a thin film transistor (TFT) as a switching element. The TFT is divided into a top-gate type and a bottom-gate type depending on the position of a gate electrode. However, both the top-gate type and the bottom-gate type TFTs include a channel layer, a gate insulating layer, a gate electrode and source/drain electrodes.

In such a TFT, the channel layer is generally made of amorphous silicon or poly-crystalline silicon. When amorphous silicon is used as the channel layer, electron mobility is low, i.e., about 1 cm²/Vcm or less, and therefore, it is difficult to apply the amorphous silicon to an active matrix OLED (AMOLED), LCD with high mobility or the like. When the poly-crystalline silicon is used as the channel layer, electron mobility is excellent, but manufacturing cost is high.

In order to solve such a problem, studies have been recently conducted to apply an oxide semiconductor to a channel layer. When the oxide semiconductor is amorphous, electron mobility is also excellent, i.e., from about 1 to about 80 cm²/Vcm, but a relatively large number of vacancies exist in the oxide semiconductor.

Meanwhile, in a TFT driven under a low gate voltage, a dielectric substance having a high dielectric constant is used rather than the silicon oxide (SiO₂) generally used as a gate insulating layer. At this time, since a large number of traps exist at the interface between the dielectric substance and another thin film layer, electric charges may be trapped in the traps. If switching operations are performed repeatedly, hysteresis is caused, and as a result, the threshold voltage may be increased.

### SUMMARY

Example embodiments have been made in an effort to solve the above-described problems associated with the prior art. Example embodiments provide a thin film transistor (TFT) capable of improving electron mobility and minimizing the occurrence of hysteresis due to traps.

Example embodiments provide a TFT including a channel layer and a gate insulating layer, wherein: the channel layer is made of an oxide semiconductor; and the gate insulating layer includes one or more first dielectric layer and a second dielectric layer, and the first dielectric layer has a dielectric constant different from that of the second dielectric layer.

According to example embodiments, the first dielectric layer may have a dielectric constant relatively smaller than that of the second dielectric layer.

The first dielectric layer may comprise any one of Al₂O₃, SiO₂ and Si₃N₄. The second dielectric layer may comprise any one of an oxide of Sc, Ti, Y, Zr, Nb, La, Hf or Ta, or an oxide of a tantalum-based element. The oxide semiconductor may be any one of ZnO, IZO, IGO, ITO, GZO, IGZO, IGTO, IZTO, SnO₂ and In₂O₃. Further, the first dielectric layer and the second dielectric layer may comprise any one of Al₂O₃, SiO₂ and Si₃N₄, but not the same material.

In the gate insulating layer, the first dielectric layer may be positioned above and/or below the second dielectric layer. And, the gate insulating layer may be formed by repeatedly laminating a double-layer structure of the first dielectric layer and the second dielectric layer.

Further, the gate insulating layer may have a structure in which the first dielectric layer, the second dielectric layer and the first dielectric layer are sequentially laminated. Further, the gate insulating layer may be formed by repeatedly laminating a triple-layer structure of the first dielectric layer, the second dielectric layer and the first dielectric layer.

Here, the first dielectric layer may have a thickness from about 5 to about 30 nm, and the second dielectric layer may have a thickness from about 30 to about 200 nm.

Example embodiments also provide a TFT including: a substrate; a channel layer formed on the substrate; source and drain electrodes formed on left and right portions of the channel layer of the substrate; a gate insulating layer formed on the channel layer; and a gate electrode formed on the gate insulating layer, wherein: the channel layer is made of an oxide semiconductor; and the gate insulating layer has a structure in which a first dielectric layer, a second dielectric layer and a first dielectric layer are sequentially formed, and the first dielectric layer has a dielectric constant relatively smaller than that of the second dielectric layer.

Example embodiments also provide a TFT including: a substrate; a gate electrode formed on the substrate; a gate insulating layer formed on an entire surface of the substrate including the gate electrode; a channel layer and an ohmic contact layer sequentially laminated on the gate insulating layer; and source and drain electrodes formed on the ohmic contact layer, wherein: the channel layer is made of an oxide semiconductor; and the gate insulating layer has a structure in which a first dielectric layer, a second dielectric layer and a first dielectric layer are sequentially formed, and the first dielectric layer has a dielectric constant relatively smaller than that of the second dielectric layer.

Example embodiments of TFT have the following advantages.

Because an oxide semiconductor layer is used as a channel layer, and a gate insulating layer is formed into a multiple-layer of one or more first dielectric layer and a second dielectric layer, which have different dielectric constants, hysteresis of the TFT is effectively minimized. Further, because a thin film is laminated using a sputtering method, processing conditions can be simplified, and manufacturing costs can be saved.

Accordingly, the TFT can be stably applied to a flat panel display such as an organic light emitting diode (OLED) or a liquid crystal display (LCD).

### BRIEF DESCRIPTION OF THE DRAWINGS

The above and other objects, features and other advantages of the present invention will be more clearly understood from the following detailed description taken in conjunction with the accompanying drawings.

FIG. 1 is a cross-sectional view showing the configuration of an example embodiment of a thin film transistor (TFT) according to the present invention.

FIG. 2 is a cross-sectional view showing the configuration of another example embodiment of a TFT according to the present invention.

FIG. 3 is a cross-sectional view showing the configuration of still another example embodiment of a TFT according to the present invention.

FIG. 4 is a cross-sectional view showing the configuration of still another example embodiment of a TFT according to the present invention.

FIG. 5A is a graph showing light transmittances of a glass substrate having only a ZnO layer laminated thereon and a glass substrate having an example embodiment of a TFT according to the present invention formed thereon.

FIG. 5B is an image of a glass substrate and a glass substrate having an example embodiment of a TFT according to the present invention formed thereon.

FIG. 6 is a graph showing transfer characteristics of a TFT manufactured according to an example embodiment of the present invention.

FIG. 7 is a graph showing results obtained by repeatedly measuring for 50 times the threshold voltage of the TFT manufactured according to the example embodiment of the present invention.

### DETAILED DESCRIPTION OF EXAMPLE EMBODIMENTS

Hereinafter, reference will be made in detail to various example embodiments of the present invention, examples of which are illustrated in the accompanying drawings and described below. While the invention will be described in conjunction with example embodiments, it will be understood that the present description is not intended to limit the invention to those example embodiments. On the contrary, the invention is intended to cover not only the example embodiments, but also various alternatives, modifications, equivalents and other embodiments, which may be included within the spirit and scope of the invention as defined in the appended claims.

In example embodiments of a thin film transistor (TFT) according to the present invention, an oxide semiconductor may be used as a channel layer, and a gate insulating layer may include one or more first dielectric layer and a second dielectric layer. Here, the first dielectric layer and the second dielectric layer may have different dielectric constants. The second dielectric layer may be made of a material having a high dielectric constant, a low leakage current and a wide bandgap. The first dielectric layer may serve as a buffer layer minimizing traps that exist at an interface with the second dielectric layer.

When the requirements for the channel layer and the gate insulating layer are satisfied, the example embodiments of a TFT according to the present invention may be applied to various types of TFTs, that is, both the top-gate type and bottom-gate type TFTs.

Hereinafter, example embodiment of a TFT according to the present invention will be described in detail with reference to the accompanying drawings.

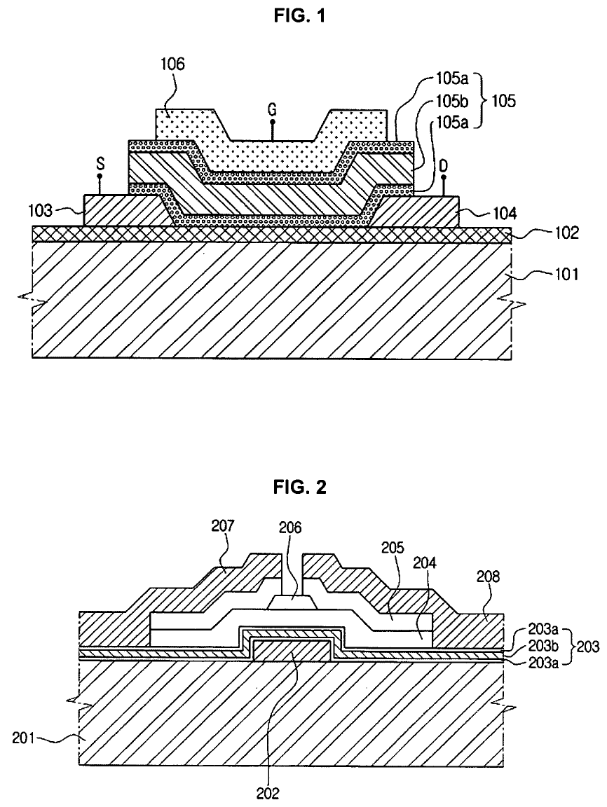

FIG. 1 is a cross-sectional view showing the configuration of an example embodiment of a TFT according to the present invention, and FIG. 2 is a cross-sectional view showing the configuration of another example embodiment of a TFT according to the present invention. Here, FIG. 1 shows a top-gate type TFT, and FIG. 2 shows a bottom-gate type TFT.

First of all, the top-gate type TFT will be described. As shown in FIG. 1, a channel layer 102 and a gate insulating layer 105 are sequentially laminated on a substrate 101, and source and drain electrodes 103 and 104 are formed on left and right portions of the channel layer 102 of the substrate 101, respectively. A gate electrode 106 is formed on the gate insulating layer 105.

The substrate 101 may include a silicon substrate, a glass substrate, a plastic substrate, or the like. The gate electrode 106 and the source and drain electrodes 103 and 104 may be a transparent electrode such as indium tin oxide (ITO), gallium zinc oxide (GZO), indium gallium zinc oxide (IGZO), indium gallium oxide (IGO), indium zinc oxide (IZO), indium gallium tin oxide (IGTO), SnO₂ or In₂O₃.

The channel layer 102 may comprise an oxide semiconductor having excellent electron mobility, such as ZnO, IZO, IGO, ITO, GZO, IGZO, IGTO, indium zinc tin oxide (IZTO), SnO₂ or In₂O₃. The gate insulating layer 105 has a triple-layer structure of a first dielectric layer 105a, a second dielectric layer 105b and a first dielectric layer 105a so as to minimize traps caused by vacancies that exist in the oxide semiconductor. The gate insulating layer 105 may be formed by repeatedly laminating the triple-layer structure of the first dielectric layer 105a, the second dielectric layer 105b and the first dielectric layer 105a.

Here, the first dielectric layers 105a respectively formed on top and bottom surfaces of the second dielectric layer 105b may comprise a material having a dielectric constant different from that of the second dielectric layer 105b. According to example embodiments, the first dielectric layer 105a may comprise a material having a dielectric constant relatively lower than that of the second dielectric layer 105b.

As an example, the first dielectric layer 105a may comprise any one of Al₂O₃, SiO₂ and SiNₓ, such as Si₃N₄. An Al₂O₃ layer is a material having a relatively high dielectric constant in spite of having low permittivity, and functions to minimize traps that exist at an interface between the Al₂O₃ layer and the oxide semiconductor and between the Al₂O₃ layer and the gate electrode 106.

The second dielectric layer 105b may comprise any one of an oxide of Sc, Ti, Y, Zr, Nb, La, Hf or Ta, and an oxide of a tantalum-based element. Particularly, HfO₂ has superior characteristics of a high dielectric constant (about 25), a low leakage current, a low-temperature depositability, a high energy bandgap (about 5.68 eV), a high transparency, and the like. Therefore, HfO₂ may be suitable to be applied to a transparent display.

According to example embodiments, the first dielectric layer 105a may comprise any one of Al₂O₃, SiO₂ and SiNₓ, and the second dielectric layer 105b may comprise any one of Al₂O₃, SiO₂ and SiNₓ, but a material different from that of the first dielectric layer 105a.

Now, the bottom-gate type TFT will be described. As shown in FIG. 2, a gate electrode 202 is formed on a substrate 201, and a gate insulating layer 203 is formed on the entire surface of the substrate 201 including the gate electrode 202. A channel layer 204 and an ohmic contact layer 205 are sequentially laminated on the gate insulating layer 203, and source and drain electrodes 207 and 208 are formed on the ohmic contact layer 205. Here, an etch stop layer 206 may be further formed on the channel layer 204.

In the bottom-gate type TFT having such a structure, materials respectively constituting the substrate 201, the gate electrode 202, the source and drain electrodes 207 and 208, the gate insulating layer 203 and the channel layer 204 may be the same as those used in the top-gate type TFT.

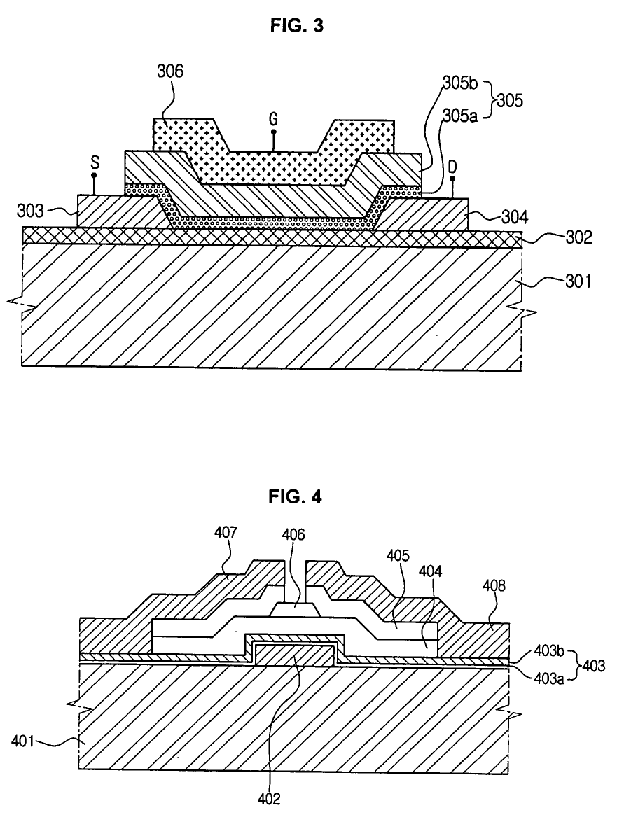

FIG. 3 is a cross-sectional view showing the configuration of still another example embodiment of a a top-gate type TFT according to the present invention, and FIG. 4 is a cross-sectional view showing the configuration of still another example embodiment of a a bottom-gate type TFT according to the present invention.

Except for the construction of gate insulating layers 305 and 403, the construction of the TFT illustrated in FIG. 3 is the same as that of the TFT illustrated in FIG. 1, and the construction of the TFT illustrated in FIG. 4 is the same as that of the TFT illustrated in FIG. 2. Accordingly, description about the embodiments illustrated in FIG. 3 and FIG. 4 will be centered on the construction of the gate insulating layers 305 and 403.

First, in the top-gate type TFT illustrated in FIG. 3, the gate insulating layer 305 has a double-layer structure of a first dielectric layer 305a and a second dielectric layer 305b so as to minimize traps caused by vacancies that exist in the oxide semiconductor. Further, the gate insulating layer 305 may be formed by repeatedly laminating the double-layer structure of the first dielectric layer 305a and the second dielectric layer 305b.

The materials that may be used in the first dielectric layer 305a and the second dielectric layer 305b are the same as those described with reference to FIG. 1. Therefore, detailed description thereof will be omitted.

Similarly, in the bottom-gate type TFT illustrated in FIG. 4, the gate insulating layer 403 has a double-layer structure of a first dielectric layer 403a and a second dielectric layer 403b. Further, the gate insulating layer 403 may be formed by repeatedly laminating the double-layer structure of the first dielectric layer 403a and the second dielectric layer 403b.

Further, the materials that may be used in the gate insulating layer 403 may be the same as those used in the top-gate type TFT described with reference to FIG. 3.

In the example embodiments illustrated in FIG. 3 and FIG. 4, the gate insulating layers 305 and 403 are illustrated to have a double-layer structure in which the first dielectric layer 305a and 403a is positioned below the second dielectric layer 305b and 403b. However, this is for the purpose of illustration only, and, in other example embodiments, the gate insulating layers 305 and 403 may have a double-layer structure in which the first dielectric layer 305a and 403a is positioned above the second dielectric layer 305b and 403b.

In the above, example embodiments of a TFT according to the present invention have been described. Hereinafter, example embodiments of a method of manufacturing a TFT according to the present invention will be described, and characteristics of the manufactured TFT will be described.

Embodiment: Manufacture of TFT

A channel layer was first formed by laminating a ZnO layer to a thickness of 50 nm on a glass substrate using an RF magnetron sputtering method. RF power was 150 W, processing pressure was 10 mtorr, processing temperature was 500° C., and a mixture gas of Ar and O₂ was used as processing gas. The reason why the ZnO layer was formed to have a thin thickness of 50 nm was to minimize interstitial sites and vacancies that exist in ZnO, and thereby to lower the high conductivity of ZnO.

Subsequently, source and drain electrodes were formed by laminating gallium zinc oxide (GZO), which is a transparent conductive material, to a thickness of 130 nm on the ZnO layer using a pulsed laser deposition (PLD) method, and then patterning the GZO using a lift-off method. ZnO target containing 5 wt % Ga was used as a target. The degree of vacuum was 1×10⁻⁵ torr, energy density was 1.6 J/cm², the distance between the target and the substrate was 4 cm, and oxygen partial pressure was 5 mtorr. For reference, the surface resistance of the laminated GZO layer was measured as 5 Ω/sq or smaller.

Thereafter, Al₂O₃, HfO₂ and Al₂O₃ were consecutively deposited to thicknesses of 10 nm, 200 nm and 10 nm, respectively, on the entire surface of the glass substrate at normal temperature using an RF magnetron sputtering method. The HfO₂ serves as a main gate insulating layer, and the Al₂O₃ formed on top and bottom surfaces of the HfO₂ serves as a buffer layer. The reason why the HfO₂ was laminated to a thickness of 200 nm was to minimize pin holes, and thereby, to secure uniform surface characteristics.

At last, a gate electrode was formed by laminating gallium zinc oxide (GZO), which is a transparent conductive material, to a thickness of 130 nm on the Al₂O₃ using a PLD method, and then patterning the GZO using a lift-off method. As a result, a TFT having a channel width of 500 μm and a channel length of 50 μm, was completed.

In the above, the example embodiment of consecutively depositing Al₂O₃, HfO₂ and Al₂O₃ to form a gate insulating layer having a triple-layer structure of a first dielectric layer, a second dielectric layer and a first dielectric layer was illustrated. However, in other example embodiments, a gate insulating layer may be formed to have a double-layer structure of a first dielectric layer and a second dielectric layer. And, the first dielectric layer and the second dielectric layer may be formed of the materials described with reference to FIG. 1.

Hereinafter, characteristics of the TFT manufactured through such processes will be described.

Light Transmittance Characteristic

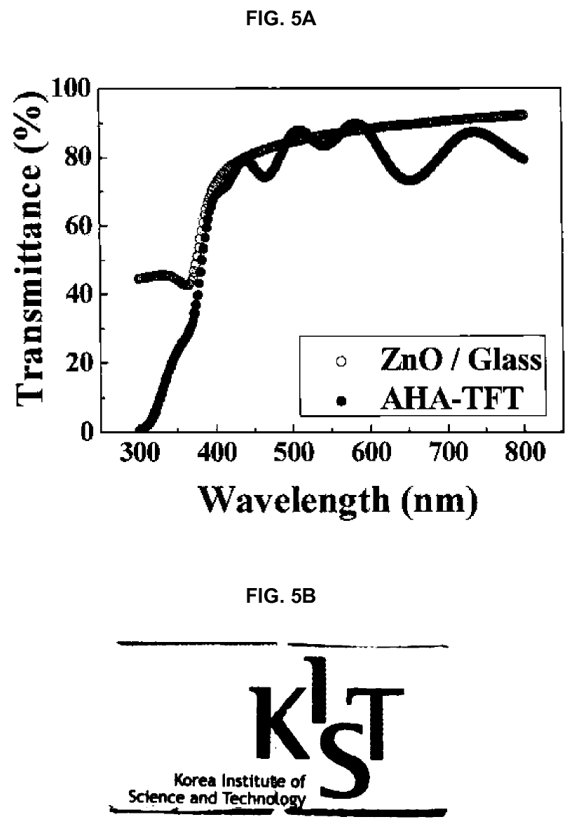

First of all, light transmittance characteristics of a TFT manufactured using example embodiments of the present invention will be described. FIG. 5A is a graph showing light transmittances of a glass substrate having only a ZnO layer laminated thereon and a glass substrate having an example embodiment of a TFT according to the present invention formed thereon, and FIG. 5B is an image of a glass substrate and a glass substrate having an example embodiment of a TFT according to the present invention formed thereon. Here, the light transmittances of FIG. 5A were measured using a UV-VIS spectrometer (Perkin Elmer, wavelength=300-800 nm), and a glass substrate having the characters “KIST” engraved thereon was used in FIG. 5B.

As shown in FIG. 5A, the average light transmittance of the glass substrate having the example embodiment of a TFT according to the present invention formed thereon was 80%, which approximates to the average light transmittance of the glass substrate having only the ZnO layer laminated thereon. As shown in FIG. 5B, in the glass having the example embodiment of a TFT according to the present invention formed thereon and the glass substrate on which nothing is formed, the characters “KIST” are clearly seen. Accordingly, there is no visibility difference between the glass substrates.

Transfer Characteristic

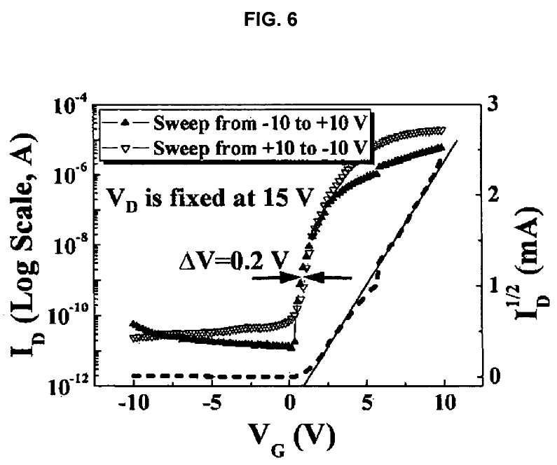

Next, transfer characteristics of the TFT manufactured using example embodiments according to the present invention will be described. FIG. 6 is a graph showing transfer characteristics of the TFT manufactured using example embodiment of the present invention. Specifically, when V_{D} is 4 V, characteristics of source-drain current I_{D} depending on the fluctuation in gate voltage V_{G} are shown.

As shown in FIG. 6, the TFT manufactured using example embodiment according to the present invention shows an on/off ratio of 5×10⁵. Further, field effect mobility is high, i.e., 12 cm²/V·s, threshold voltage Vₜₕ is low, i.e., 1.0 V, and sub-threshold swing (SS) is excellent, i.e., 0.52 mV/dec. Since a low voltage difference of 0.2 V at a current of 10⁻⁹ A is shown, it can be seen that hysteresis is effectively minimized.

Threshold Voltage Fluctuation Characteristic

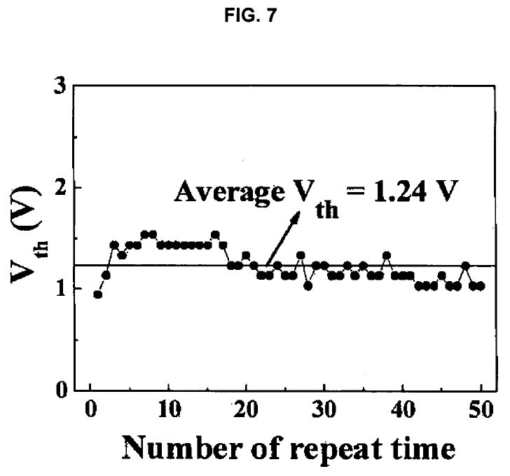

Next, threshold voltage fluctuation characteristics of the TFT manufactured using example embodiments of the present invention will be described. FIG. 7 is a graph showing results obtained by repeatedly measuring for 50 times the threshold voltage of the TFT manufactured using example embodiments of the present invention.

As shown in FIG. 7, the threshold voltage Vₜₕ repeatedly measured for 50 times is from 0.94 to 1.51 V, and the average threshold voltage is 1.24 V. Therefore, the deviation is not large. This shows that the low voltage driving of the TFT can be performed stably.

Although example embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A thin film transistor (TFT), comprising a channel layer and a gate insulating layer, wherein:
the channel layer is made of an oxide semiconductor; and
the gate insulating layer includes one or more first dielectric layer and a second dielectric layer, and the first dielectric layer has a dielectric constant different from that of the second dielectric layer.

2. The TFT according to claim 1, wherein the first dielectric layer is positioned above and/or below the second dielectric layer.

3. The TFT according to claim 2, wherein the gate insulating layer is formed by repeatedly laminating a double-layer structure of the first dielectric layer and the second dielectric layer.

4. The TFT according to claim 1, wherein the gate insulating layer has a structure in which the first dielectric layer, the second dielectric layer and the first dielectric layer are sequentially laminated.

5. The TFT according to claim 4, wherein the gate insulating layer is formed by repeatedly laminating a triple-layer structure of the first dielectric layer, the second dielectric layer and the first dielectric layer.

6. The TFT according to claim 1, wherein the first dielectric layer comprises any one of Al₂O₃, SiO₂ and Si₃N₄.

7. The TFT according to claim 1, wherein the second dielectric layer comprises any one of an oxide of Sc, Ti, Y, Zr, Nb, La, Hf or Ta, and an oxide of a tantalum-based element.

8. The TFT according to claim 1, wherein the first dielectric layer and the second dielectric layer comprise any one of Al₂O₃, SiO₂ and Si₃N₄, and the first dielectric layer and the second dielectric layer comprise different material.

9. The TFT according to claim 1, wherein the oxide semiconductor comprises any one of zinc oxide (ZnO), indium zinc oxide (IZO), indium gallium oxide (IGO), indium tin oxide (ITO), gallium zinc oxide (GZO), indium gallium zinc oxide (IGZO), indium gallium tin oxide (IGTO), indium zinc tin oxide (IZTO), SnO₂ and In₂O₃.

10. The TFT according to claim 1, wherein the first dielectric layer has a dielectric constant relatively smaller than that of the second dielectric layer.

11. The TFT according to claim 1, wherein the TFT is a top-gate type TFT or a bottom-gate type TFT.
